(19) United States
(12) Patent Application Publication
(10) Pub. No.: US 2006/0087350 A1
(43) Pub. Date: Apr. 27, 2006

(54) Frequency divider with variable division rate

(76) Inventor: David Ruffieux, Lugnorre (CH)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 10/548,957

(22) PCT Filed: Mar. 3, 2004
(86) PCT No.: PCT/CH04/00120

§ 371 Date: Sep. 15, 2005

(30) Foreign Application Priority Data
Mar. 18, 2003 (FR) 03/03300

(51) Int. Cl. H03B 19/00

(52) U.S. Cl. 327/117

(57) ABSTRACT

A frequency divider is provided that comprises a plurality of chain-connected cells, the output of the last cell of the chain being fed back to the input of the first cell. Each cell has an inverter, the transition of which can be enabled or inhibited by control transistors connected in series with the circuit of the inverter between positive and negative supply terminals. The frequency signal to be divided is applied to the gates of these transistors. The divided frequency signal is delivered to the output of the last cell of the chain of cells. According to one implementation, in one of the cells of the chain of cells, one of the transistors having one of the conductivity types, is connected in parallel to a short-circuit transistor of the same conductivity type and the gate of the short-circuit transistor is connected so as to be able to be turned on by a control signal for changing the division factor.

The present invention relates to a frequency divider with a division factor of unity and to applications of this divider.

In electronics, there is a need for some applications to have a frequency divider whose division factor can be varied from unity according to the state of a control signal. One of these applications is that of frequency synthesizers used in RF transmit/receive circuits, especially for allowing communication on a plurality of channels.

Frequency dividers of this type have therefore already been developed in the past. One of the known constructions comprises D-type flip-flops (bistable multi vibrators) that are associated with a control logic, making it possible, through the action of a control signal, to set the division factor for example to 2 or to 3, to 3 or to 4, or else to 15 or to 16. At higher frequency, the flip-flops can still be used in special technologies (ECL (Emitter-Coupled Logic), SCL (Source-Coupled Logic) etc.) but their consumption quickly becomes very high.

Also known are dynamic frequency dividers with a fixed division factor produced in CMOS technology and comprising a plurality of “chain-connected” cells one after another, the output of the last cell being fed back to the input of the first cell, and each cell including an inverter, the transition of which can be enabled or inhibited by transition control transistors of p and n type respectively, that are connected in series with the circuit of the inverter between positive and negative supply terminals, the frequency signal to be divided being applied to the gates of these control transistors, it being possible for said signal to be in direct form or in differential form. The number of chain-connected cells therefore determines the division factor.

Such dividers have the advantage of being simple and to consume only very little power, but they are not designed for varying their division factor.

The object of the invention is to provide a frequency divider of the type described above, but the division factor of which can be varied from unity, while however preserving its advantage of low power consumption and simplicity.

The subject of the invention is therefore a frequency divider with a variable division factor of unity, this divider being produced in CMOS technology and comprising a plurality of chain-connected cells, the output of the last cell of the chain being fed back to the input of the first cell, and each cell having an inverter, the transition of which can be enabled or inhibited by transition control transistors of p type and n type respectively that are connected in series with the circuit of the inverter between positive and negative supply terminals of the divider, the frequency signal to be divided being applied to the gates of these transition control transistors and the divided frequency signal being delivered to the output of the last cell of said chain of cells, this divider being characterized in that, in one of the cells of said chain of cells, one of said transition control transistors of one of the conductivity types is connected in parallel to a short-circuit transistor of the same conductivity type and in that the gate of said short-circuit transistor is connected so as to be able to be turned on by a control signal for changing the division factor.

Thus, for each of the two logic levels of the control signal, the divider has division factors that differ from unity.

According to other advantageous features of the invention:

the transition control transistor, belonging to the cell following that which includes a short-circuit transistor and of conductivity type opposite that of the latter, is also connected in parallel with a second short-circuit transistor that is controlled by the complement of said control signal for changing the division factor;

the gate of one of said short-circuit transistors is connected directly to a control terminal designed to receive said control signal and the gate of the other short-circuit transistor is connected to said control terminal via an inverter;

since the divider is of singular type, it comprises an odd number (2n+1) of cells and the gates of all the transition control transistors are connected so as to receive the same logic level of the signal to be divided, the division factor being of the 2n/2n+1 type;

since the divider is of differential type, it comprises an even number (2n) of cells plus a branch having an inverter, in each of the successive cells of said chain of cells, the gate of the transition control transistor of one conductivity type is connected so as to receive a first logic level of said frequency signal to be divided and the gate of the control transistor having the other conductivity type is connected to the complementary logic level of said frequency signal to be divided and in successive cells of said chain of cells, the connection of these gates is inverted, the division factor of said divider being of (2n−1/2n) type.

the inverter of each cell includes two transistors of opposite conductivity type that are connected in series with said transition control transistors, the gates of the transistors of said inverter being connected together, forming the input of the cell, and the drains of these transistors being connected in series with the drains of said transition control transistors of said cell;

it is connected in cascade to at least one divider with a fixed division factor, comprising a second plurality of cells that are connected in a second chain, the output of the last cell of this second chain being fed back to the input of the first cell of this second chain, and each cell of the latter having an inverter, the transition of which can be enabled or inhibited by second transition control transistors of p type and n type respectively that are connected in series with the circuit of the inverter between positive and negative supply terminals of the divider, the output signal of said divider being applied to the gates of these second control transistors, a divided frequency signal being delivered to the output of the last cell of said second chain of cells, and said divider with a fixed division factor also including a logic circuit designed to generate said signal for changing the division factor according to the logic state of the outputs of predetermined cells of said second chain of cells of said divider with a fixed division factor.

The subject of the invention is also a frequency synthesizer comprising a phase lock loop having a frequency divider that has the characteristics as defined in the characterizing part of claim 1.

The subject of the invention is also a frequency synthesizer that includes a frequency divider having some or all of the features as defined above.

Other features and advantages of the present invention will become apparent during the following description, given solely by way of example and with reference to the appended drawings in which:

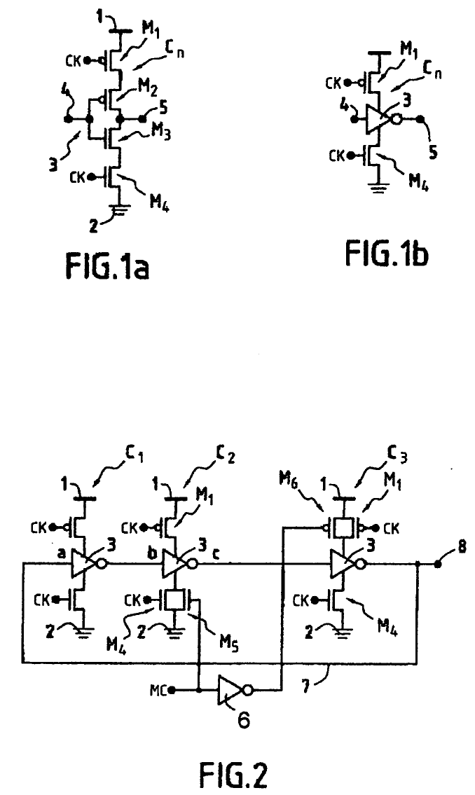

FIGS. 1a and 1b show a diagram of a preferred embodiment of a base cell of a divider according to the invention, allowing frequency division with a division factor that can be varied from unity;

FIG. 2 is a diagram of such a divider using the base cell shown in FIG. 1 and making it possible to obtain a 2/3 settable division factor;

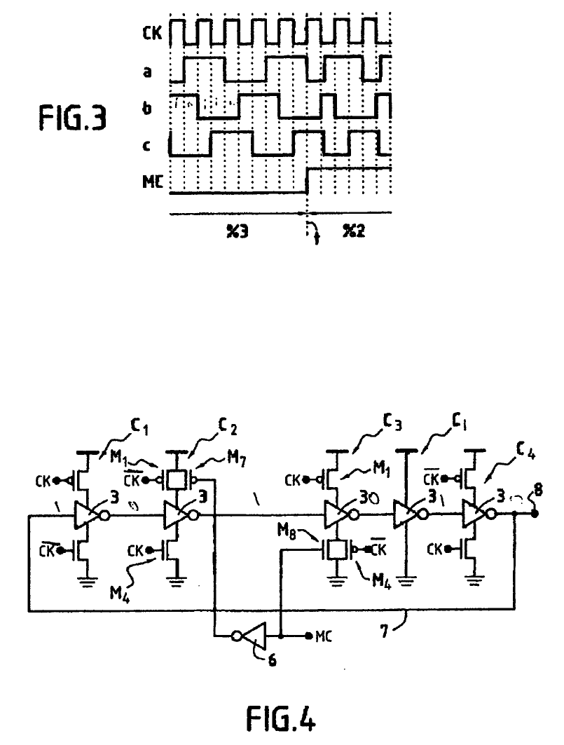

FIG. 3 is a timing diagram illustrating the operation of the divider with variable division factor of FIG. 2;

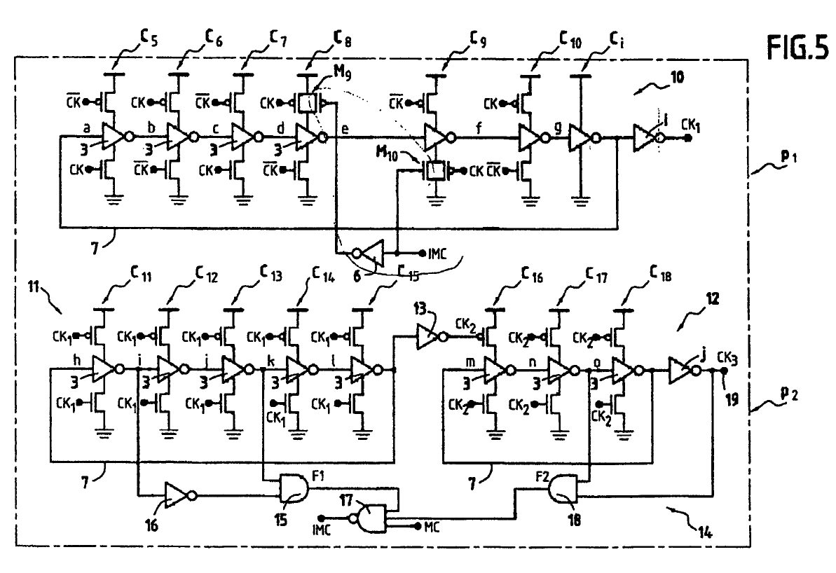

FIG. 4 shows the diagram of another divider according to the invention, the division factor of which may vary between 3 and 4;

FIG. 5 shows a diagram of another divider according to the invention, the division factor of which can vary between 75 and 76;

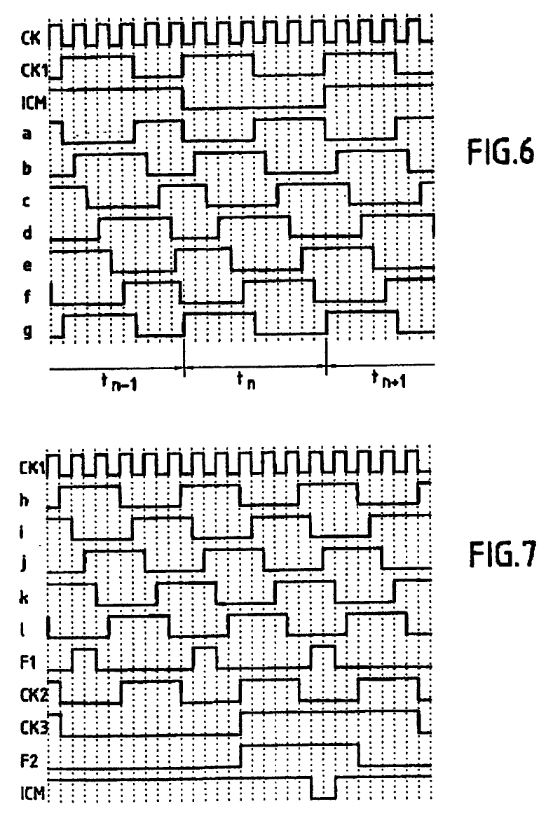

FIGS. 6 and 7 show two timing diagrams, with different timescales, illustrating the operation of the 75/76 divider according to FIG. 5; and

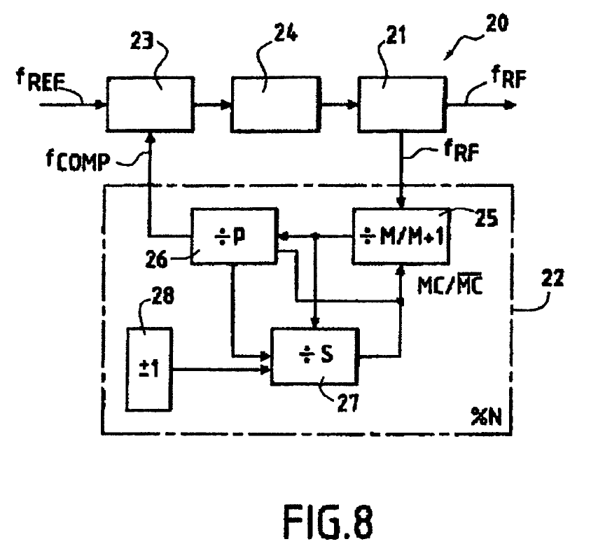

FIG. 8 is a block diagram of a frequency synthesizer in which a divider according to the invention with a division factor that can be varied from unity is used.

FIG. 1a shows the diagram of a base cell Cₙ of the divider according to the invention. This cell Cₙ comprises the series connection of four transistors M₁ to M₄ connected between the positive supply conductor 1 and the negative (earth) supply conductor 2 of a voltage source (not shown). The transistors M₁ and M₂ are of p type and the transistors M₃ and M₄ are of n type, the sources of the transistors M₁ and M₄ being connected to the supply conductors 1 and 2, respectively.

As shown in FIG. 1b, the transistors M₂ and M₃ constitute an inverter 3, it being possible for a pulse applied to the input 4 of this inverter 3 to appear in complementary form at the output 5. The input 4 is connected to the gates of the transistors M₂ and M₃, while the output 5 is connected to the drains of said transistors.

In the diagrams shown in FIG. 1, it is assumed that the cell Cₙ belongs to one type of divider, called a “singular” divider, as opposed to a divider called a “differential” divider. In the first case, shown in FIG. 1, the frequency signal CK to be divided is asymmetrical, whereas in the second case said signal is of symmetrical waveform, through its direct waveform and its complementary waveform. Examples of differential type dividers will be described below.

In the base cell Cₙ of FIG. 1, which is of the singular type, the frequency signal to be divided is therefore applied in its direct form to the gates of the two transistors M₁ and M₄ that act as controlled current sources or switches.

In the rest of the figures, the transistors M₂ and M₃ of each cell will be represented in the simplified form of the symbol of an inverter, as may be seen in FIG. 1b.

FIG. 2 shows the simplest form of a frequency divider according to the invention, it being possible for this divider to work in divide-by-two mode or in divide-by-three mode. It comprises three base cells C₁, C₂, C₃ designed according to the model of FIG. 1 and “chain-connected” one after another. This divider is therefore also of the “singular” type.

To allow switching from one division mode to the other, this divider requires only a single additional switch formed by an n-type or p-type transistor, the source-drain path of which is connected in parallel with one of the transistors of the same type (for example M₅) of one of the branches. However, it is possible to add a second additional switch (M₆) formed by a transistor of opposite type to the first one, and the source-drain path of which is connected in parallel with the transistor M₁ of the next cell (cell C₃), in order to increase the speed of the divider. The gates of these transistors M₅ and M₆ are connected, directly and via an inverter 6 respectively, to a division mode control terminal MC.

In the divider according to the invention, which always comprises an odd number of cells, the inverters 3 of successive cells, here the cells C₁, C₂ and C₃, are “series-connected” or “chain-connected” to one another, the output 5 of an upstream cell being connected to the input 4 of a downstream cell. Furthermore, the set of cells is connected in a ring, the output of the last cell, in this case C₃, being connected to the input of the first cell, in this case C₁, via a feedback conductor 7. Owing to this connection principle, the arrangement therefore forms a kind of ring oscillator. The divided-frequency output signal can be taken off from any terminal, but preferably off a terminal where the transitions are synchronized by the clock signal CK.

FIG. 3 shows a timing diagram illustrating the operation of the divider with variable division factor that has just been described. This timing diagram shows the change between the divide-by-three mode and the divide-by-two mode that occurs at time t, that is to say, in the example, when the control signal MC switches from the low logic level to the high logic level. The signals a, b and c in FIG. 3 correspond to the input signals of the three inverters 3 of the cells C₁, C₂ and C₃, respectively.

Up to time t, the transitions of the output signals b, c and a of the inverters 3 of the three cells C₁, C₂ and C₃ each take place with a delay of one half-period of the signal CK to be divided on the transition of their input signal. For example, when the signal c has the low level, the signal a at the input of the inverter 3 of the cell C₁ (and consequently the signal on the output 8) switches to the high level only when the switches M₁ and M₄ of this cell C₃ are turned on by the frequency signal CK to be divided. What is therefore obtained on the output 8 of the circuit is a signal whose frequency is in a ratio of 1 to 3 relative to the signal CK.

After time t, when the control signal MC adopts the high level, and as soon as the signal b switches from the low level to the high level, the signal c switches to the low level and the signal a switches to the high level before the transition of the frequency signal CK occurs, since the transistor M₅ and the transistor M₆ then short-circuit the transistors M₄ and M₁ of the cells C₂ and C₃ respectively, these transistors having been turned on by the control signal MC. There therefore remains in the output signal on the terminal 8 only the trace of three half-cycles, followed by a half-cycle, i.e. two cycles of the signal CK, which amounts to dividing the frequency by a factor of two, instead of a division by three before the transition of the control signal MC. Of course, when the latter returns to the low level, the divider will again divide by three.

FIG. 4 shows a diagram of a differential-type divider capable of carrying out a division by three or a division by four of a frequency signal whose direct waveform CK and complementary waveform \overline{CK} applied alternately to the transistors M₁ and M₄, respectively, are used in successive cells, as shown.

In this case, the divider comprises an even number of cells (four cells C₁ to C₄ designed according to the diagram of FIG. 1a as per the example) and a single inversion cell Cᵢ in order to obtain a ring with an odd number of branches, this being required in order to have an oscillator. It may be seen that, in this case too, all the cells are chain-connected and that the last cell C₄ is fed back to the first cell C₁ via the feedback conductor 7. To allow selection of the three or four division factor, this divider requires only a single additional switch, but it is much more rapid with two switches of opposite type (for example M₇ and M₈) placed in two consecutive branches. The operation is similar to that of the divider shown in FIG. 2 and therefore requires no further explanation.

FIG. 5 shows another embodiment of a divider designed according to the invention. This divider uses both a differential-type part p₁ and a singular-type part p₂. It is designed to operate selectively with division by 75 or division by 76.

The part p₁ comprises a divider 10, the division factor of which may be set to 5 or 6 depending on the level of an applied signal applied to a terminal IMC. This divider 10 is constructed on the model of the divider already described with regard to FIG. 4. It comprises six chain-connected cells C₅ to C₁₀, the cells C₈ and C₉ being provided with an additional short-circuit transistor, M₉ and M₁₀ respectively, to the gates of which are applied the output of an inverter 6 and the control signal IMC, respectively, the latter signal also being applied to the input of this inverter.

The direct frequency signal CK to be divided and the complement \overline{CK} of this signal are applied alternately to the cells C₅ to C₁₀. The cell C₁₀ is followed by a simple inversion cell Cᵢ, the output of which is fed back onto the input of the first cell C₅ via the feedback conductor 7. The output of the inversion cell Cᵢ is also connected to an inverter i that delivers the intermediate signal CK, divided by 5/6 from the frequency signal CK. In fact, it should be noted that the output signal is available at the output of any cell.

The part p₂ of the divider with a 75/76 division factor comprises two elementary dividers 11 and 12, with a constant division factor of 5 and 3 respectively, the first comprising five cells C₁₁ to C₁₅ and the second three cells C₁₆, C₁₇ and C₁₈. The cells of the divider 11 are chain-connected, the output of the cell C₁₅ being fed back onto the input of the cell C₁₁ via a feedback conductor 7. A similar structure is provided for the divider 12.

The direct waveform of the intermediate signal CK₁ is applied to all the gates of the switching transistors of the divider 11, whereas a second intermediate signal CK₂, which is the complement, obtained by means of an inverter 13 (which is also called a “buffer”) of the output signal of the last cell C₁₅ of the divider 11, is applied to all the cells of the switching transistors of the divider 12. To simplify the drawing, the conductors on which the intermediate signals CK₁ and CK₂ travel have not been shown.

The intermediate control signal IMC is generated by a logic circuit 14. This comprises a first AND gate 15, a first input of which is connected via an inverter 16 to the output of the cell C₁₂ of the divider 11 and the other input of which is connected to the output of the cell C₁₃ of this same divider. The output of the AND gate 15 is connected to the first input of a NAND gate 17.

The logic circuit 14 also includes a second AND gate 18, the first input of which is connected to the output of the cell C₁₇ of the divider 12 and the other input of which is connected to the output of an inverter j connected downstream of the last cell C₁₈ of this same divider. The output of this inverter j constitutes at the same time the output 19 of the entire divider 10, onto which output the desired signal CK₃ is delivered, this signal being formed by the signal CK divided either by 75 or by 76.

The output of the AND gate 18 is connected to a second input of the NAND gate 17. That is activated by the control signal MC, which is applied to its third input and determines the change from unity of the division factor of the divider 10. The output of the NAND gate 17 delivers the intermediate control signal IMC.

The timing diagrams of FIGS. 6 and 7 illustrate the operation of the dividers 10 and 11/12, respectively, the literal references corresponding to the outputs of the cells as indicated in FIG. 5.

When the divider 10 operates in divide-by-5 mode (see the timing diagram of FIG. 6, at time intervals tₙ₋₁ and tₙ₊₁), the division factor is equal to 5×5×3=75, since the dividers 11 and 12 divide the signal CK₁ by 5 and the signal CK₂ by 3, respectively. In this case, the intermediate control signal IMC is in the high state, so that the switches M₉ and M₁₀ are on. Two half-cycles of the signal CK are therefore neutralized each time and as soon as the signal d switches from the high level to the low level, the corresponding cells awaiting the transition of the signal CK before switching.

To make the divider 10 operate in divide-by-6 mode (see the timing diagram of FIG. 6, time interval tₙ), the intermediate control signal IMC must be brought to the low level once every 15 periods of the signal CK₁. The 76 division factor is then obtained, which will be achieved by dividing, for each complete division cycle, 14 times by 5 and once by 6 (76=14×5+1×6). To do this, the output of the AND gate 15 is held at the high level for a duration that corresponds to the duration of one period among five of the signal CK, and the output of the AND gate 18 is held at the high level for one period in three of the signal CK₂. The two output signals F_{1 and F}₂ of these gates are combined logically in the NAND gate 17 and may thus result in the division by 76, while the control signal MC is at the low level.

One particularly advantageous application of the invention will now be described with reference to FIG. 8, which shows a simplified diagram of a frequency synthesizer 20, the output frequency f_{RF} of which can be varied and may be a variable multiple of an input frequency f_{REF}. The latter frequency is obtained for example from a source (not shown) that delivers a very stable reference frequency by means of a quartz oscillator. A synthesizer of this type, which is known per se, can be used for example in an RF application in which information can be disseminated and received on several channels having different frequencies.

The synthesizer 20 comprises an oscillator 21 controlled by a voltage that is set by a phase lock loop comprising a frequency divider 22, with a stepwise-variable division factor N, which sends a comparison frequency f_{COMP} to a phase comparator 23. This comparator is designed to deliver at its output a voltage that is adjusted so that the frequency and the phase of the signals that it receives (the frequency f_{REF} and the frequency f_{COMP}) are the same. The adjusted voltage is applied to a low-pass filter 24 which is designed to reduce the high-frequency fluctuations thereof before it is applied as control voltage to the oscillator 21.

The divider 22 comprises a divider 25 with a division factor that can be varied from unity (division by M or by M+1), which is such as that shown and described with regard to FIGS. 1 to 7, the number of its cells and of its dividers, and also its two division factors, being chosen so as to allow stepwise adjustment of the frequency f_{RF} over a desired range of variation. These two factors are therefore not necessarily those of the dividers that were described above.

The divider 25 divides the frequency f_{RF} coming from the oscillator 21 by M or M+1 and transmits the divided signal to a counter 26 that can count up to a number P and to a counter 27 that can count up to a number S, where S<P. The capacity of the counter S may be modified in units in both directions, thanks to a frequency value control shown symbolically by the block 28 on which a user of the synthesizer can act in order to vary the division factor N and therefore the ratio of the frequencies f_{RF} and f_{REF}.

Assume initially that the divider 25 is set to the division factor M+1 (equal to 76 for example, as in the example shown in FIG. 5). The counter S then fills up, and when it is full (M+1)×S cycles of the signal f_{RF} will have passed. The counter 27 is inhibited and sends a control signal MC to the divider 25, which therefore modifies its division factor, taking the value M (for example equal to 75). The counter 26 fills up in turn, and when M×(P−S) cycles have passed, this counter will also be full. The counters 26 and 27 are reset to zero and the complementary signal MC is applied to the divider 25, the division factor of which again becomes equal to M+1, and so on. Over one complete filling cycle of the counter 26, that is to say of the signal at the frequency f_{COMP}, a value of N equal to (M+1)×S+M×(P−S)=M×P+S is therefore obtained. If the capacity of the counter 27 is incremented or decremented by unity by means of the control 28, it is possible to obtain a variation of one step, in one direction or the other, of the ratio between f_{RF} and f_{REF}.

Another application of the divide-by-N divider 22 described above may be envisaged for producing an inhibit circuit well known in clock technology so as to adjust the timebase of a clock circuit. In this case, the frequency of the timebase of this clock circuit may be set stepwise on the basis of a high-frequency quartz oscillator, it being possible for the inhibition then to take place in the division chain of the clock circuit at a stage located close to the quartz oscillator, instead of being close to the output of the division chain, which output beats seconds. This may result in substantially improved precision in the inhibition compared with conventional inhibit circuits that adjust the timebase to a low frequency in a division stage located close to the output of the division chain.

1. A frequency divider with a variable division factor of unity, the divider being produced in CMOS technology and comprising a plurality of chain-connected cells, the output of the last cell of the chain being fed back to the input of the first cell, and each cell having an inverter, the transition of which can be enabled or inhibited by transition control transistors of p type and n type respectively that are connected in series with the circuit of the inverter between positive and negative supply terminals of the divider, the frequency signal to be divided being applied to the gates of these transition control transistors, and the divided frequency signal being delivered to the output of the last cell of said chain of cells,
wherein in one of the cells of said chain of cells, one of said transition control transistors of one of the conductivity types is connected in parallel to a short-circuit transistor of the same conductivity type and the gate of said short-circuit transistor is connected so as to be able to be turned on by a control signal for changing the division factor.

2. The divider according to claim 1, wherein the transition control transistor, belonging to the cell following that which includes a short-circuit transistor and of conductivity type opposite that of the latter, is also connected in parallel with a second short-circuit transistor that is controlled by the complement of a control signal for changing the division factor.

3. The divider according to claim 2, wherein the gate of one of said short-circuit transistors is connected directly to a control terminal designed to receive said control signal and the gate of the other short-circuit transistor is connected to said control terminal via an inverter.

4. The divider according to claim 1, wherein the divider comprises an odd number (2n+1) of cells and the gates of all the transition control transistors are connected so as to receive the same logic level of the signal to be divided, the division factor being of the 2n/2n+1 type.

5. The divider according to claim 1, wherein the divider comprises an even number (2n) of cells plus a branch having an inverter, wherein in each of the successive cells of said chain of cells, the gate of the transition control transistor of one conductivity type is connected so as to receive a first logic level of said frequency signal to be divided, and the gate of the control transistor having the other conductivity type is connected to the complementary logic level of said frequency signal to be divided and, in successive cells of said chain of cells, the connection of these gates is inverted, the division factor of said divider being of the 2n−1/2n type.

6. The divider according to claim 1, wherein the inverter of each cell includes two transistors of opposite conductivity type that are connected in series with said transition control transistors, the gates of the transistors of said inverter being connected together, forming the input of the cell, and the drains of these transistors being connected in series with the drains of said transition control transistors of said cell.

7. The divider according to claim 1, wherein the divider is connected in cascade to at least one divider with a fixed division factor, the divider comprising a second plurality of cells (C₁₁ to C₁₅) that are connected in a second chain, the output of the last cell of this second chain being fed back to the input of the first cell of this second chain, and each cell of the second plurality of cells having an inverter, the transition of which can be enabled or inhibited by second transition control transistors of p type and n type respectively that are connected in series with the circuit of the inverter between positive and negative supply terminals of the divider, the output signal of said divider being applied to the gates of these second control transistors, a divided frequency signal being delivered to the output of the last cell of said second chain of cells, and said divider with a fixed division factor also including a logic circuit designed to generate said signal for changing the division factor according to the logic state of the outputs of predetermined cells of said second chain of cells of said divider with a fixed division factor.

8. A frequency synthesizer, comprising a phase lock loop having a frequency divider as claimed in any one of claims 1 to 7.
